(19) United States
(12) Patent Application Publication
(10) Pub. No.: US 2009/0166329 A1
(43) Pub. Date: Jul. 2, 2009

(54) PROCESS AND MARKER INSTALLATION FOR AN OBJECT

(75) Inventors: Jorge Cors, Geneva (CH); Oystein Fischer, Coppet (CH); Olivier Kuffer, Le Grand-Saconnex (CH); Jean-Marc Triscone, Plan-les-Ouates (CH); Michel Decroux, Pregny-Chambesy (CH)

Correspondence Address: YOUNG & THOMPSON, 209 Madison Street, Suite 500, ALEXANDRIA, VA, 22314, US

(73) Assignee: L'UNIVERSITE DE GENEVE, Geneve (CH)

(21) Appl. No.: 12/373,949

(22) PCT Filed: Jul. 10, 2007
(86) PCT No.: PCT/IB2007/001934

§ 371 Date: Jan. 15, 2009

(30) Foreign Application Priority Data
Jul. 19, 2006 (CH) 01163/06

(51) Int. Cl. B44C 1/22; C23C 14/48

(52) U.S. Cl. 216/67; 427/523

(57) ABSTRACT

The invention relates to a method and an installation for identifying an object. An identification mark (12) is made on the actual object using electrical discharges (28) between a metal tip (21), such as that of a local-probe microscope, and the substrate (22) formed by the object. The discharges (28) are produced through a composite dielectric medium (25) and produce an impression (23) which can be identified by read means, such as a microprobe, and has a particular physical nature and/or a particular chemical composition. Thanks to these characteristics, it is possible to obtain a very secure identification and authentication mark that can be applied directly to the actual object to be identified or authenticated.

The present invention is concerned with a process of marking of an object comprising the affixation of at least one identification mark in at least one site of a substrate of this object.

Numerous technologies have been implemented in order to guarantee the identity or authenticity of objects of value, such as works of art, pieces of jewelry and historical objects. A medium for combating the fraudulent forgery of such objects is the insertion of a plaquette for identification that comprises a marker with a specific code. The present invention has the aim or improving known techniques, and to obtain a process that is very safe, practically unviolable, and allows affixing an identification mark directly on the object to identify or authenticate.

It further aims at improving the marker techniques that will allow the identification of objects for the purpose of tracing pieces or lots of fabrication, quality control, or any other activity relative to object tracing.

To this effect, the invention is characterized by the characteristics appearing in claim 1, and in particular by the fact that this mark of identification is accomplished by using at least one electric discharge between a metal point and said substrate, so as to obtain at least one identifying impression representing a particular physical nature and/or chemical composition that is situated next to this site, where this impression forms the mark of identification that can be read by means of reading.

These characterics allow one to obtain a process of identification or authentication that is very safe and reliable, and where the marks of identification or authentication can be applied directly on the object being authenticated.

Advantageously, the metal point is separated from the substrate by a predetermined distance or gap occupied by a dielectric medium where the discharge is produced by forming an ionized plasma canal.

Thanks to these characteristics, highly precise and reproducible identifying impressions can be obtained.

Favorably, the dielectric medium is constituted by a dielectric liquid, gel, or paste the molecules of which contain as constituting elements one or several chemical elements that are intended to be implanted into the substrate.

Favorably, the dielectric medium includes at least one powder having a grain size distribution much finer than the gap filled with dielectric liquid, gel, or paste, and the chemical composition of the powder is selected as a function of chemical composition of the substrate, so as to obtain an impression of a chemical composition distinguishing itself from the substrate.

One thus obtains a microreactor which yields a large variety of identifying impressions that can be used in numerous applications.

The invention also concerns an installation for the identification of an object that comprises a device for the production of at least one identifying mark at one site of a substrate of this object in the least, which is characterized by the fact that the device for the production comprises at least one metallic point, a device for displacement allowing one to accomplish a relative displacement between the metallic point and the substrate in order to attain a predetermined distance or gap between the point and the substrate to this site, and means for producing at least one dielectric discharge between the point and the substrate, in order to obtain on the substrate at least one impression representing a particular physical nature and/or chemistry situated next to this site, while means of reading are provided to recuperate this impression forming the identifying mark.

Other advantages will arise from the characteristics expressed in the dependent claims and in the description which hereinafter will expose the invention in greater detail with the aid of drawings representing schematically and in an exemplary fashion an embodiment.

FIG. 1 shows an object intended to be used in a marking process according to the invention.

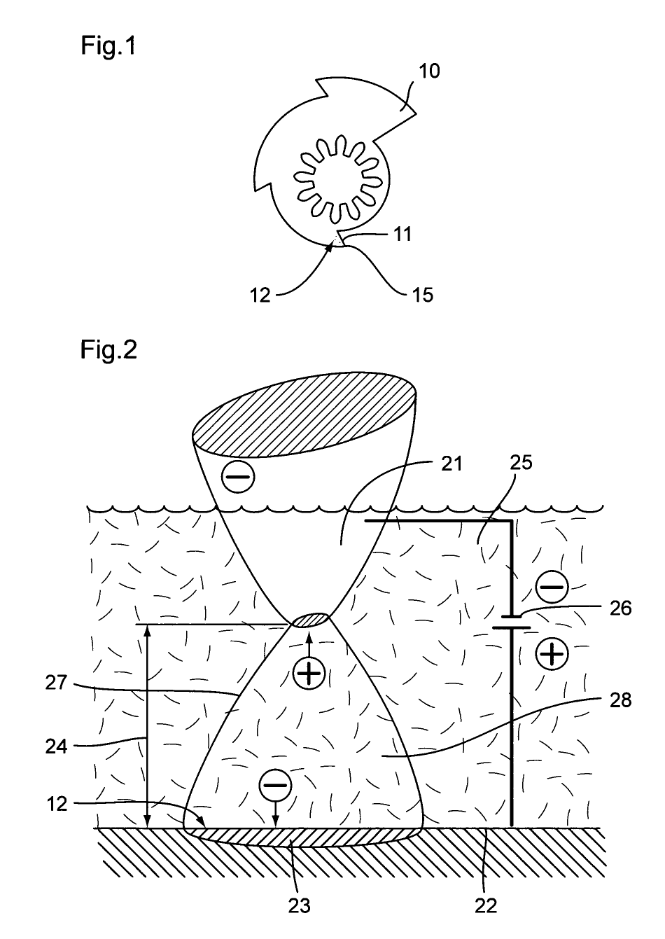

FIG. 2 shows in detail the formation of a microdischarge and of an impression constituting an identifying mark.

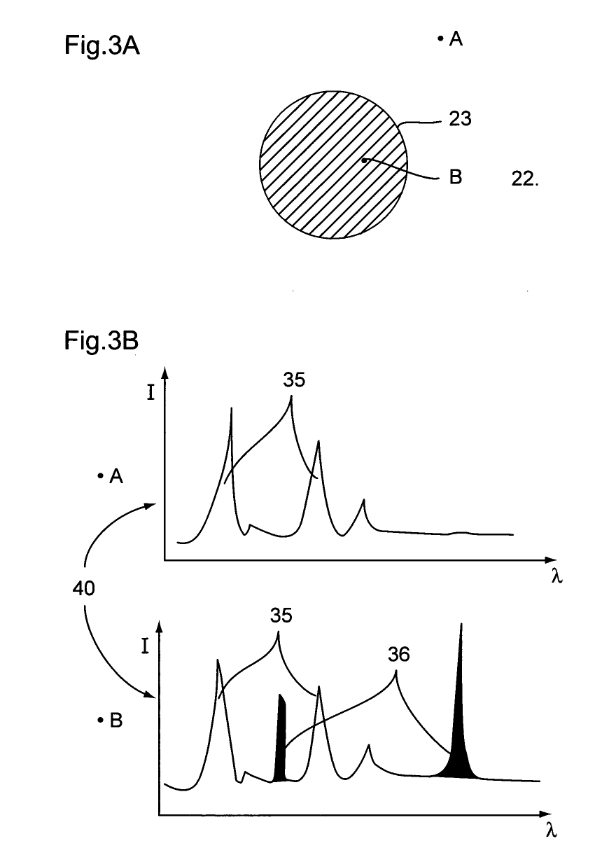

FIG. 3A is a top view of such an impression.

FIG. 3B illustrates two measurements of chemical composition made at sites A and B of FIG. 3A by microprobe or EDX equipment.

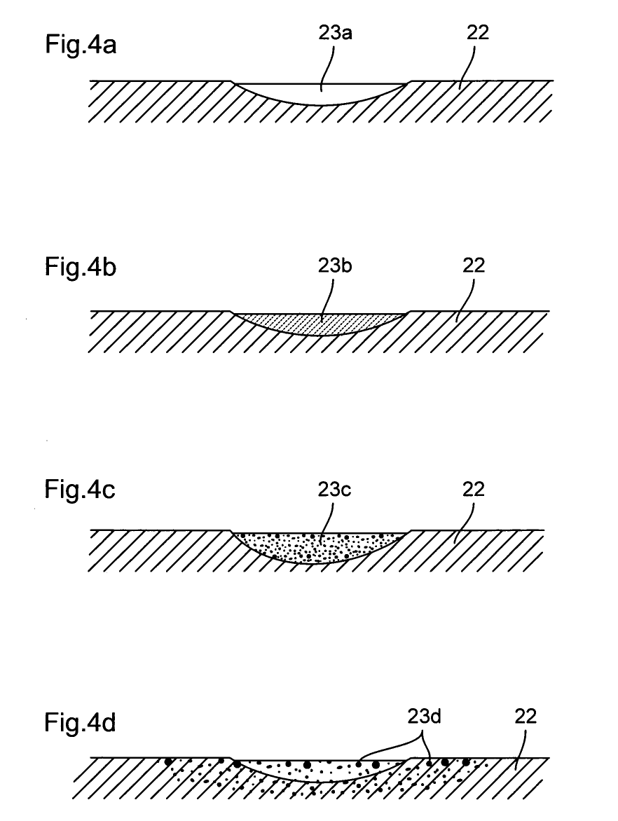

FIGS. 4a b is 4d illustrate four types of impressions obtained by microdischarge.

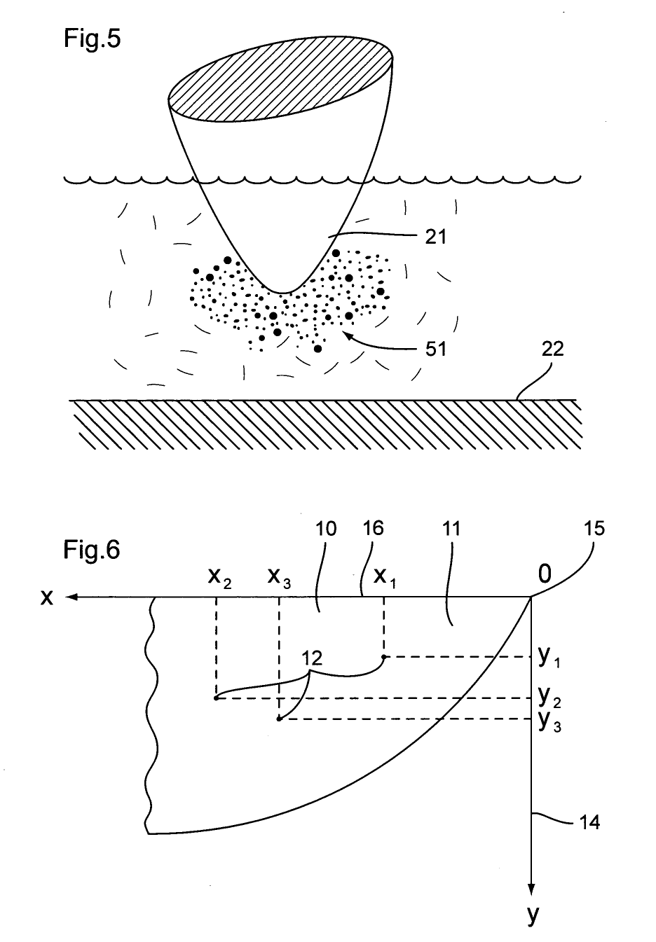

FIG. 5 represents a variant of microdischarge.

FIG. 6 is a magnified view of FIG. 1.

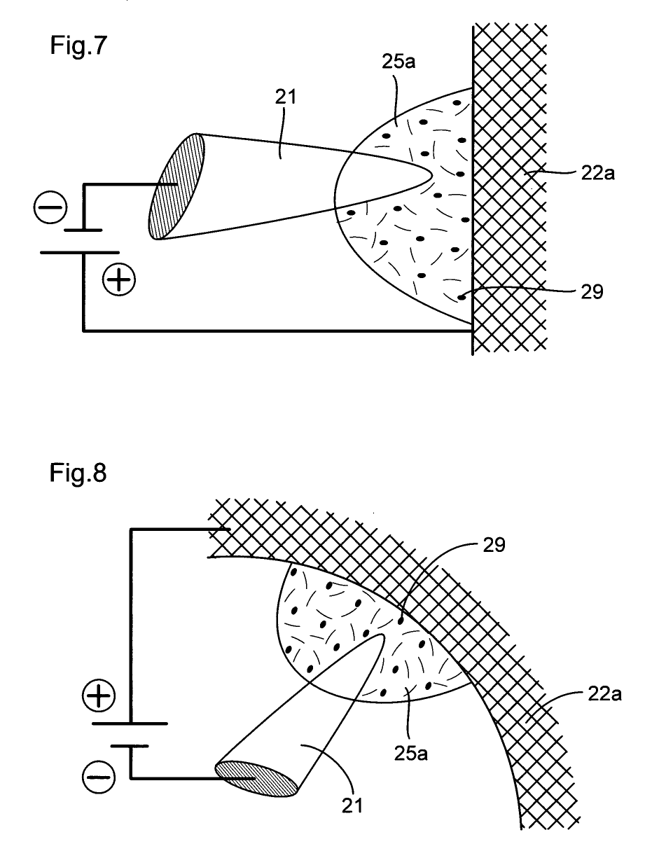

FIGS. 7 and 8 illustrate variants of the marking process using a semisolid dielectric medium in the form of gel or paste.

According to a first embodiment of the invention, one or several identifying or authenticating marks are applied directly on the object to identify or authenticate, such as for example the snail 10 in watchmaking illustrated in FIG. 1.

To do so, one will need to determine on this object at least one macroscopic characteristic 11, for instance the last tooth of the snail.

On this macroscopic characteristic 11a particular place is defined, e.g., the point of the tooth that is going to serve as the point of reference or geometrical origin 15 of a system of coordinates.

Then one calculates the coordinates xi, yi of the sites that these identifying marks 12 should occupy with the aid of predetermined coding algorithm characteristic of a means of identifying attributed to the object. Then the identifying marks will be realized at these calculated emplacements.

According to this embodiment, while referring to FIG. 2 for the identifying marks one applies a marking technique that uses electric discharges between a very fine metallic point 21 such as that of a local-probe microscope, an atomic-force microscope (AFM) or tunnel-effect microscope (STM), or that between the end of a fine metallic wire and the substrate surface 22, for example the surface of the object to be identified, for the purpose of creating on those sites an impression 23 of the particular chemical composition and/or physical nature constituting one of the identifying marks 12. The point 21 and the substrate 22 are separated by a distance or gap 24 of some micrometers, typically between 1 μm and 200 μm. This gap is entirely filled with a composite dielectric medium 25 in which the discharge 28 (a microdischarge) is produced.

This microdischarge is obtained by allowing point 21 to approach one of said predetermined sites of the substrate surface 22 while all of it is immersed into a dielectric medium. By means of a condenser 26, a generator or any other current source, a voltage typically comprised between 1 V and 400 V is applied between the point 21 and the substrate 22 in order to produce a breakdown or microdischarge in the dielectric medium. One sees then the formation of a conducting ionized plasma canal 27 between the point 21 and the substrate 22. An electric current coming from the discharge of the condenser 26 or any other source of current can traverse the ionized plasma. The energy thus furnished contributes to the formation of a microplasma that is confined to very high temperatures and pressures.

In the scheme of FIG. 2, point 21 works as the cathode and substrate 22 as the anode. This scheme shows the state of the discharge 28 immediately after breakdown of the dielectric medium. However, the polarities could be inverted.

The plasma mass surrounded by a gaseous envelope or gas bubble grows during discharge, which typically takes between 1 and 800 μs. However, the radial expansion of the plasma is strongly restricted by the dielectric medium, and the energy of the discharge is found to be concentrated in a very small volume. The ultrahot plasma radiates its energy toward to surface of electrodes producing metal fusion. The mass of the plasma is actually constituted of molecules of the composite dielectric medium that have been pulverized and dissociated by the energy of the discharge. The elevated temperature of the plasma provokes the melting of a surface that has the form of a disk of some tens of micrometers, typically from 0.5 μm to 200 μm. However, the elevated pressure of the plasma limits the evaporation of molten matter from the electrodes. This mechanism results in the formation of quasi circular impressions of metal melted into the routes of the arc. The dimension of the disk of molten metal is a direct function of the discharge time.

According to a variant of the process, one can draw out the point in a plane when the arc has been established, and make lengthy marks or lines and other, more complex trajectories without extinguishing the arc, in the manner of a micro-blowpipe. In this case the arc may be maintained during several seconds and more.

In the case of FIG. 2, the configuration with a cathodic point and an anodic substrate is particularly favorable. The anode undergoes very rapidly the electronic bombardment right at the beginning of the discharge, and this actually constitutes the reason for metal melting. The cathode will only be reached by positive ions—much heavier and less mobile—until much later, and in the worst of cases. On the other hand, since the cathode emits electrons, the plasma diameter on the cathode is also much smaller.

By controlling the energy the discharge, its lifetime, the distance of breakdown and/or gap 24, and above all the chemical composition and additives present in the dielectric medium 25, the discharge plasma is used as a microreactor for producing impressions of molten metal with chemical compositions other than those in the base substrate.

Point 21 can be made of any metal, but preferably it will be a refractory metal like tungsten, iridium, platinum, molybdenum and any other metal having a high melting point or other thermionic emission properties. The high melting point provides minimum wear of the point, and the electronic thermionic emission properties are effective in discharge to melt the cathode and cool the cathode.

For the composite dielectric medium 25, nanopowders of different metals can be used. These fine or ultrafine powders with mean diameters in the order of a nanometer, typically from 1 nanometer to 10 micrometers and preferably from 1 nm to 200 nm, are mixed into a dielectric liquid of predetermined viscosity, generally mineral oils or deionized water. The viscosity of the dielectric medium can be high when a semisolid dielectric in the form of gel or paste is used.

Since the dimensions of the powder particles are much smaller than the distance between point and surface (FIG. 2), these particles are volatilized by the discharge, and the corresponding chemical elements are then found in the plasma. After interaction with the plasma, these elements are then fixed on the roots of the arc at the substrate surface. By analysis with the microprobe or EDX analysis (energy-dispersive X-ray analysis), the presence of such elements can be revealed on the substrate at the place of discharge, which constitutes the signature of implant as represented in FIGS. 3A and 3B. FIG. 3A shows the impression 23 of the microdischarge on the substrate 22, FIG. 3B shows two EDX analyses 40 performed at points A and B. These EDX analyses reveal the constitutive elements 35 of the substrate at point A and an additional doping element 36 coming from the composite dielectric medium at point B.

The composite dielectric liquid, gel, or paste is therefore a solution containing nanoparticles or microparticles, and can be considered as a metallurgical ink. As a matter of fact, in the place of colors one can use different compositions with variable ratios of different metals. This ink is selected as a function of the piece to mark; for instance, if a steel containing iron, chromium, and nickel is concerned, nanoparticles of tungsten or silicon will be selected. The chemical composition of the powder is therefore chosen as a function of chemical composition of the substrate, so as to obtain an impression 23 having a chemical composition that is distinct from that of the substrate 22. Thus, the association of a heavy metal such as gold will yield silicium as a very hard and resisting alloy forming the impression of the identifying mark. A homogeneous distribution of nanoparticles in the dielectric medium is obtained for instance by the addition of a surfactant in the dielectric liquid or gel, such as an adequate soap. The molecules of this surfactant are arranged on the surface of the nanoparticles, cancel the attractions of the Van der Waals forces and hinder their coalescence or flocculation, thus stabilizing the composite dielectric. The discharge may also be accomplished in a composite emulsion such as a gas containing droplets in suspension.

The electric parameters of the discharge, such as the form of current pulse, its strength and lifetime and the number of discharges, will allow different types of impression to be obtained which go from the formation of a new alloy to a simple “welding” of the micro or nanoparticles on the surface.

One may thus cite the types of impressions 23 forming the identifying marks 12 by following the references in FIG. 4:
4a) The simple substrate metal melt without any additive, but with the possible formation of amorphous alloys 23a.
4b) The formation of a new alloy containing at least one new chemical element coming from the dielectric 23b.
4c) The implant of at least one new element coming from the dielectric in the native alloy of the substrate 23c.
4d) The microwelding or adhesion of particles 23d coming from the dielectric. As the liquid metal becomes first pasty, then solid, it may capture elements present in the dielectric in the moments following discharge when the plasma cools. This capture could even happen in the vicinity of the impression near the route of the arc on a sufficiently hot thermal column.

This latter type of impression allows particles to be captured without denaturing them. In particular, powders or nanopowders that become fluorescent after exposition to ultraviolet rays, such as salts doped with rare earths, may thus be fixed with the purpose of an antifraudulent marker, for instance.

The configuration in a single discharge 28 or several successive discharges at the point of a local-probe microscope in a well defined site allows one to control all parameters of the formation of impressions 23. In particular, the gap 24 can be adjusted to nanometers by piezoelectric actuators, in order to obtain reproducible impressions contrary to electroerosion where the discharge is produced in indetermined fashion with a large variation of the gap.

The discharge type can be a condenser discharge, or the current can also be furnished by an ad-hoc generator or any other source of current after breakdown of the composite dielectric. The lifetime of discharge, the amplitude of the current as well as the pulse form are optimized for the implantation of the ions contained in the dielectric.

The density of the composite dielectric or, rather, the concentration of the ions 36 at the place of discharge can be guided by a magnetic field produced by a coil that is displaced together with the point 21. An effect of agglomeration 51 that is controlled under the point 21 is thus obtained. The same effect of agglomeration of or preconcentration can be obtained by electrostatic attraction toward a point that is polarized by an adequate voltage. The attraction may be magnetic and/or electrostatic. The nanoparticles can also be preconcentrated on the point just prior to discharge by electrostatic attraction (FIG. 5). The polarities used for build-up of the discharge and for maintenance of the discharge can be different.

Thus, an identifying mark is obtained in the following fashion with the substrate and the point immersed into the composite dielectric medium. One places point 21 over the site where one wants to accomplish this identifying mark or impression. The precise positions in X and Y can be made by precise displacements of a X-Y table and/or the point itself. It is in fact a movement of the point relative to the substrate. With the aid of a micrometric, mechanical or piezoelectric actuator one makes contact with the substrate 22 by using an electric resistance measurement, for example. Then one withdraws the point to the distance wanted, by fixing the gap to the next nanometer.

Then one applies a voltage to point 21, and after breakdown or build-up one discharges the energy stored in a condenser or other source of current through the plasma channel 27 until the discharge is extinguished, which produces the impression 23.

This technique for making an identifying or authenticating mark has the advantage that it will adapt
to the physical properties of the piece to mark, such as the melting point, the thermal conductivity, etc.; this adaptation happens via the energy of discharge;
to the surface state or roughness of the piece, via adjusting the diameter of the impression;
to the chemical composition of the piece to mark, via selection of the composite dielectric medium;
to the type of implant desired, by the selection of the energy and form of discharge.

Relative to traditional electroerosion, this process is distinguished by the following facts:
a) The conditions of the discharge are perfectly defined, particularly the distance of breakdown (gap) and the physicochemical composition of the dielectric in the gap.
b) The X-Y coordinates of the microdischarge are established with precision. The geometry with a fixed point assures a maximum of electric field at a very precise place.
c) The vicinity of the discharge is reproducible. The discharges are in principle identical and reproducible. In the gap of electroerosion, to the contrary, on has a liquid boiling (bubbles, debris, chaotic movement of the liquid). Also, the friction forces of the liquid vitrified by the pressure on the surface of the electrodes are variable between discharges. In the present case, the geometry used for discharge is always the same.

This technique allows metallic or semiconductor objects to be marked. It may be adapted to the marking of insulating objects, for example of glass, by using a counterelectrode disposed close to point 21 and to the surface of the object.

It is understood that this embodiment could well receive all other modifications that could be desired.

Thus, the point could make an anode, and the substrate a cathode.

One could plan the deposit of materials from the point toward the substrate.

The dielectric medium could equally well be a gas such as air or a gas with fine particles in suspension, for instance acetylene with silicium that would be integrated into the impression, or again a gel or paste.

FIG. 6 explains more in detail the determination of the site or sites that should be occupied by the authentifying mark or marks 12.

For reasons of the microscopic or nanoscopic size of the identifying mark or marks, a process and means of guidance are indispensable for realizing and finding the identifying mark or marks by reading means. In fact, the surface observation field of the means of reading is highly reduced, and it is quasi impossible for this reason to find these macroscopic or nanoscopic marks if one does not know their positions.

The definition of a system of coordinates and guidance of the identifying marks with the aid of a macroscopic characteristic are important elements of the present invention.

The process is schematically shown in FIG. 6. In this case the last tooth of the snail 10 is used as a macroscopic characteristic 11 to define a reference system of coordinates 14 to realize and then read or observe the identifying marks 12. A characteristic or particular spot of this tooth is selected and defined as the coordinate origin 15, here its point. The orientation of the axis X of the coordinate system will be that of the straight surface 16 of this tooth, for instance, and will serve as reference system for the orientation.

As these characteristics are readily fixed with the aid of an optical microscope, one positions the point 21 with the uttermost precision possible on the kinking. One can then use a micrometic X-Y table for centering this point 21 precisely. The position x, y that is displayed be the X-Y table corresponds to the geometric origin of the coordinate system.

The writing and reading of the identifying marks 12 will then be made from this geometrical original 15 of the coordinate system 14.

One calculates the coordinates xᵢ, yᵢ of the sites that should be occupied by the identifying marks, with a calculator and coding algorithm by using an identifying means attributed to an object that one wishes to identify or authenticate.

This identifying means could for instance be an identification number attributed to an object, such as its serial number or a fraction of it. A series of coordinates xᵢ, yᵢ in units of micrometers that correspond to the different identifying marks 12 will then be calculated with the coding algorithm, which remains secret and the property of the user.

This addressing system can for instance use rectangular coordinates. Mathematical relations allow a series of n points xᵢ, yᵢ to be calculated from any serial number N or any other reference number determined by the user.

The relations are determined or at any rate known and kept confidentially by the user.

According to a very simple example the coordinates are determined with the following EXCEL formula:

X1=ARRONDI.INF(MOD(constante x, y+Numéro de série; 100); 0)*10.

According to another variant, any point of an identifying mark will serve as a now point of reference in order to find the next mark.

Identifying marks 12 in the form of impressions 23 will then be realized at the sites for which one has calculated the coordinates xᵢ, yᵢ.

For a verification of the identity or authenticity of the object one obtains the coordinates of said sites by calculation, places the means of reading such as a microprobe or electronic microscope together with EDX equipment (energy-dispersive X-ray analysis) on said coordinates, and controls the presence of identifying marks on these sites.

The relative size and the scale of marks in FIG. 6 do not correspond to reality, of course.

In reference to FIGS. 7 and 8, the dielectric medium may favorably consist of a semisolid substance 25a, a gel, or a paste. This substance is pure or mixed with different additives 29, to be implanted into the substrate 22a. This gel or paste offers no physical resistance to the vertical or horizontal displacement of the metal point 21 used for marking, and most gels or pastes on the basis of hydrocarbons such as vaseline are translucent in the thicknesses applied for this evaluation.

As dielectrics, electrically insulating gels or pastes like vaseline, grease on the basis of hydrocarbons or joint grease can be used. Liquids of very high viscosity like silicone or poly(dimethylsiloxane) oil (PMDS oil) can also be used for this.

The viscosity of this gel or paste is selected so that the dielectric medium will not run off even when arranged on an inclined or vertical surface.

The use of dielectric gel or paste produces the following advantages in particular:
The solution obtained when mixing intimately the gel or paste with different powders and nanopowders is stable and uniform, there is no sedimentation nor agglomeration between the constituents that cannot freely be displaced within the dielectric medium. In the case of a liquid dielectric, the powders may sediment or be displaced in uncontrolled fashion on the surface of the piece to be marked, which can be detrimental to the uniformity of chemical marking.
An important advantage for users is the use of gel for the marking of complex surfaces, vertical (FIG. 7), inclined (FIG. 8), or other, where a liquid that can run off is not adequate.
The gel or paste does not evaporate. Once applied, the thickness remains constant, which is comfortable for the user. Further, since they do not spread, different gels or pastes containing different powders can be disposed simultaneously in very close fashion without the formation of mixtures between the gels. This allows a multiple chemical marking on reduced surfaces.
Finally, the configuration with a semisolid dielectric allows an important number of different chemical elements to be added. An emulsion is much more tolerant than a liquid when producing a homogeneous mixture of different constituents. Thus, one may plan the inclusion of elements like sulfur, selenium, or tellurium in order to reduce the surface tension of the molten metal and obtain a better adhesion of the identifying mark. One may add to the dielectric, appropriate elements such as silicium or phosphorus that are susceptible to favor the formation of an amorphous alloy or a metallic glass that is much harder than an ordinary alloy. One may equally will enclose powders on the basis of rare earths like europium or praseodymium. All these additions may be realized simultaneously in a gel or paste in order to obtain an optimum mixture for a given application.

It is understood that the modes of realization that have been described above are not at all limiting, and that they may receive all desirable modifications within the framework as defined by claim 1. In particular, instead of realizing a single discharge at a predetermined site, one may realize two or more discharges at the same site or at offsites.

The marking may also consist of a series or marks of close nanoscopic or microscopic size disposed on the surface so as to form a periodic or pseudo-periodic series or network of marks. One such series of marks could be suitably identified by an observation of the surface with the aid of an optical system or local probe, the acquisition of a surface image and subsequent mathematical treatment of the image for example by autocorrelation. In particular, a Fourier transform process can be used in order to prove the presence and location of a series or artificial periodic marks. This embodiment could even be realized on a rough surface where the individual identification of isolated nanoscopic marks could be a problem.

Also, the marking could consist of a series of discharges allowing the physicochemical surface composition of a fraction of the surface of the object to be marked, to be modified.

Also, microscopic marks of a particular physicochemical composition could suitably be dissimulated on a surface having a roughness identical with that which would be produced if identical marks not doped without change in the surface composition would be present on the entire surface on a large scale.

For example, advantageously the chemical marking by differential composition could be made on a surface machined by electroerosion. The identifying marks would then be dissimulated on such a surface, and would practically not be found without a key for geometric coding.

In addition, the process can be used for marking an intermediate piece intended to produce by replication a large number of identical objects having microscopic marks. In particular, the process can be applied to the surface of a mold in order to allow production of microprotuberances on the molded pieces.

The marking may also be made on a given site by one or by several successive discharges. Thus, a second discharge at the same place may modify and even improve the implant quality of the mark. The type of electric pulse, its polarity and again the distance between point and surface may also vary between successive discharges. One may equally well superimpose discharges partially, by doing a micrometrical lateral displacement with the point in order to create a particular geometry.

In a variant, one could accomplish lateral displacements of the point during discharge for the purpose of creating particular geometric figures like geometric drawings, symbols, and letters. In this case the arc may be maintained for several seconds and more.

The marking may be produced directly on the surface of the object to identify or authentify, or on the surface of a plaquette serving as a substrate, where this plaquette would be fixed by all adequate means on the object to be identified.

Where the dielectric medium is concerned, a liquid, gel, or paste offers an elevated molecular concentration that will be appropriate for the creation of a dense plasma. At the same time the liquid or gelatinous medium will allow the point electrode to remain mobile on the surface to be marked.

As liquid or gel can be used:
mineral oils or grease, deionized water, vaseline or any other dielectric liquid or gel having the dielectric properties required for obtaining a breakdown;
dielectric liquids or gels where the molecules as constitutive elements contain the element or elements that one wishes to implant into the surface of the piece to be marked. For example, if one wants to implant silicium one will use silicone oil or grease. In general, however, one can use any other liquid or gel of appropriate molecular composition which will go a very long way, such as liquid crystals. By selecting the molecular composition, one makes sure that the ions desired for implantation into the discharge plasma are present.
These same liquids or gels contain powders in suspension (emulsions).

The use of a liquid or semisolid dielectric allows in addition to the elements intended to do the chemical marking, to add other additives that may favor the breakdown of the dielectric under the applied electric field, which is a phenomenon just as important for this application. In fact, the addition of metal or semiconductor microparticles to a dielectric reduces in considerable fashion the resistance to breakdown under the effect of an electric field. However, the effect is so much more pronounced when the additions have fiber shape with a very large relation of length to diameter. In the framework of this application it is essential to obtain a breakdown of the dielectric when an electric voltage difference is applied on the point. This breakdown is produced at any rate if one comes sufficiently close to the point of the surface even in an undoped dielectric. However, for certain applications of marking it will be preferable to remain a certain distance of micrometers from the surface, either in order to diminish the risk of adhesion or welding at the point on the surface or in order to increase the mass of the plasma or quantity of material volatilized by the discharge. The key point is that the filiform additions must not perturb the chemical dose that has been administered to the dielectric, that is, they must have a negligible mass. Such inclusions are for example known under the name of nanotubes or nanorods. Initially discovered for the element of carbon, the nanorods and nanotubes nowadays exist for a large choice of elements such as Cu, Mo, Ag, Pb or compounds like WO₃ and MoO₃. In the case of carbon nanotubes, their dimensions may attain some nanometers in diameter but several tens of micrometers in length. Ratios of length to diameter of the order of 100 000 are known, and one may expect 500 000. Such particles favor considerably the breakdown of the dielectric at comfortable distances from the surface. The use of carbon nanotubes having a certain length is also a means for adjusting the distance of breakdown. A composite dielectric containing the doping elements as well as nanotubes and/or nanorods therefore constitutes a composite dielectric that is very adequate for the use of the present invention.

The invention has applications not only for an authentication of objects such as objects of value, but equally well for a marking to identify objects that will permit the tracing of pieces or lots of pieces from fabrication, the control of quality or any other activity in relation to the tracing of objects. This marking is particularly adequate for the marking of critical pieces in systematic fashion. In this way one can track down the different lots of fabrication. The microscopic or nanoscopic nature of marking respects the physical and functional integrity of the piece to be marked, since a physical contact between the point and the piece is absent. The only force exerted on the object to be marked comes from the pressure of the microplasma.

The chemically doped impressions can attain dimensions of several hundred micrometers, and in addition to their role of authentifying marks, they can also be arranged on mosaic fashion in order to form decorative figures on the surface of objects to be marked.

The use of a sacrificial thin layer can be planned in order to make sure that a dopant element is present. A fine metal film disposed in advance on the substrate will then be used to furnish the dopant element. The microdischarge will fuse this film, and mix it with the native alloy that underlies it.

An object already covered by a metal layer, such as a rhodiated piece of jewelry, could be marked by practicating an opening by microdischarge in the coating. Analysis by EDX will then reveal the presence of the base alloy that only exists in the place of marking.

The band of electrical voltages to be used to provoke the breakdown of the dielectric can be extended from 1 V to 400 V. The point effect allows the voltage difference to be lowered, in order to obtain a local electrical field that is sufficiently high for breakdown to be brought about at the precise spot.

1. Process of marking of an object comprising the affixing of at least one identifying mark to at least one site of a substrate (22) of this object, characterized in that one accomplishes this identifying mark (12) by using at least one dielectric discharge (28) between one metal point (21) and said substrate (22), for obtaining at least one impression (23) representing a particular physical nature and/or chemical composition to said site, this impression (23) forming the mark of identification (12) that can be recovered by means of reading (40).

2. Process according to claim 1, characterized in that the impression (23) is produced on the surface of the object to be identified that forms the substrate (22).

3. Process according to claim 1, characterized in that the point (21) is separated from the substrate by a predetermined distance (24) or gap occupied by a dielectric medium (25) in which the discharge is produced to form an ionized plasma canal (27).

4. Process according to claim 3, characterized in that the dielectric medium (25) consists of a dielectric liquid, gel, or paste the molecules of which contain as constitutive elements one or several chemical elements intended to by implanted in said substrate (25).

5. Process according to claim 2, characterized in that the dielectric medium (25) comprises at least one powder that has a finer grain size distribution than the gap mixed with a dielectric liquid, gel, or paste, the chemical composition of the powder having been selected as a function of the chemical composition of the substrate so as to obtain an impression (23) of a chemical composition distinguishing it from that of the substrate (22).

6. Process according to claim 1, characterized in that the point (21) forms a cathode, and the substrate (22) forms an anode or the inverse.

7. Process according to claim 1, characterized in that the point (21) consists of a refractory metal having an elevated melting point and/or thermionic emission properties, that point being a local-probe microscope or the end of a wire.

8. Process according to claim 3, characterized in that the substrate (22) is a metal or semiconductor, and that at least one of the following types of impression (23) is obtained as a function of the electrical parameters of the discharge between the point (21) and the substrate (22):
the simple melting of the substrate without modification of its chemical composition, with the possible formation of amorphous alloys (23a);
the formation of a new alloy containing at least one new element coming from the dielectric medium (23b);
the implantation of at least one chemical element coming from the dielectric medium in the substrate (23c);
the micro-welding or adhesion of particles coming from the dielectric medium on the substrate (23d).

9. Process according to claim 3, characterized in that the identifying mark (12) is obtained
by placing the point (21) on said site, the substrate (22) and the point (21) being immersed into the dielectric medium (25),
by obtaining a mechanical contact between the point (21) and the substrate (22) by means of a micrometric, mechanical, or piezoelectric actuator, when controlling the contact advantageously by the measurement of electric resistance,
by separating the point (21) and the substrate (22) by a predetermined gap,
by applying a voltage difference between the point (21) and the substrate (22), and after breakdown of a discharge, discharging the energy coming from a condenser or source of current through the ionized plasma canal (27).

10. Process according to claim 4, characterized in that one determines by means of a microprobe or EDX equipment that form said means of reading, the chemical composition of the impression (23) relative to that of the substrate (22) in order to verify the identity of the object.

11. Process according to claim 1, characterized in that one determines on the substrate (22) at least one macroscopic characteristic (11) that can be referenced by optical means,
that one defines a particular spot (12) of the macroscopic characteristic (11), to serve as a reference point and geometric origin (15) or a system of coordinates (14),
that one calculates the coordinates (xᵢ, yᵢ) of the emplacement or emplacements that should be occupied by the identifying mark or marks (12) with the aid of a coding algorithm using a means of identification attributed to the object,
that one realizes the identification mark or marks (12) at the sites where the coordinates (xᵢ, yᵢ) have been calculated, these marks of identification being not able to be referenced by the naked eye but by means of reading,
that one verifies the identity of said object by obtaining the coordinates (xᵢ, yᵢ) of the emplacement of the identifying mark or marks (12), and by placing the means of reading on said coordinates in order to control the presence of the identifying mark or marks (12) on the site or sites.

12. Process according to claim 1, characterized in that one accomplishes a series of identifying marks (12) forming a network of marks susceptible of being identified by said means of reading, followed by a mathematical treatment that favorably is a Fourier treatment.

13. Process according to claim 3, characterized in that one uses as dielectric medium a gel or paste having a viscosity such that the dielectric medium will not flow out even when disposed on an inclined or vertical surface.

14. Process according to claim 3, characterized in that the dielectric medium comprises additions of microparticles in the form of fibers intended to reduce the resistance to breakdown under the action of an electric field, these fibers favorably consisting of nanotubes.

15. Installation of the identification of an object comprising a device for production of at least one identifying mark (23) on at least one site of a substrate (22) of this object, characterized in that the device for production comprises a metal point (21), a device for displacement permitting to accomplish a relative displacement between the point and the substrate so as to obtain a predetermined distance or gap between the point (21) and the substrate (22) to this site, and the means (26) for producing at least one electric discharge between the point and the substrate so as to obtain on the substrate at least one impression (23) representing a particular physical nature and/or chemistry situated to this displacement, the means of reading being planned to reference this impression (23) forming the identifying mark (12).

16. Installation according to claim 15, characterized in that it comprises a predetermined dielectric medium (25) disposed between the point (21) and the substrate (22) where an electric discharge is produced to form an ionized plasma channel (27).

17. Installation according to claim 16, characterized in that the dielectric medium (25) consists of a dielectric liquid, gel, or paste the molecules of which contain as constitutive elements one or several elements intended to be implanted into said substrate (22).

18. Installation according to claim 16, characterized in that the dielectric medium (25) comprises at least one powder having a grain size distribution finer than the gap mixed with a dielectric liquid, gel, or paste, the chemical composition of the powder being selected as a function of chemical composition of the substrate in such a fashion that an impression (23) of a chemical composition is obtained which is distinguished from that of the substrate (22).

19. Installation according to claim 15, characterized in that the point (21) consists of a refractory metal having a high melting point and/or thermionic emission properties, this point (21) being that of a local-probe microscope or end of a wire and preferably forming a cathode, while the substrate (22) constitutes an anode.

20. Installation according to claim 15, characterized in that the means of reading consist of the microprobe or EDX equipment susceptible of determining the chemical composition of the impression (23) relative to that of the substrate (22) so that the identity of the object can be verified.

21. Installation according to claim 15, characterized in that it comprises
means for determining a macroscopic characteristic (11) that can be recovered by optical means, and for defining a particular place of this macroscopic characteristic (11) intended to serve as reference system and geometric origin of a system of coordinates,
means for calculating the coordinates (xᵢ, yᵢ) of at least one site that should be taken up by the identifying mark (12) with the aid of a coding algorithm using an identifying means attributed to the object, and
means for reading, in order to verify the identity of said object, which are apt to control the presence of the identifying mark (12) on the site for which one has calculated the coordinates.
